(19) United States
(12) Patent Application Publication
(10) Pub. No.: US 2012/0153332 A1
(43) Pub. Date: Jun. 21, 2012

(54) EPITAXIAL STRUCTURE OF AN LED AND MANUFACTURING METHOD THEREOF

(75) Inventors: PO-MIN TU, Hukou (TW); SHIH-CHENG HUANG, Hukou (TW); YA-WEN LIN, Hukou (TW)

(73) Assignee: ADVANCED OPTOELECTRONIC TECHNOLOGY, INC., Hsinchu Hsien (TW)

(21) Appl. No.: 13/326,337

(22) Filed: Dec. 15, 2011

(30) Foreign Application Priority Data
Dec. 21, 2010 (CN) 201010595677.6

(51) Int. Cl. H01L 33/44; H01L 33/20

(52) U.S. Cl. 257/98; 438/29; 257/E33.067; 257/E33.074

(57) ABSTRACT

An epitaxial structure of a light emitting diode (LED) includes a substrate, an epitaxial layer, and a light capturing microstructure. The substrate has a top surface. The epitaxial layer is grown on the top surface of the substrate and has a P-type semiconductor layer, an active layer, and an N-type semiconductor layer in sequence. The light capturing microstructure is positioned on an upper portion of the epitaxial layer which is distant from the substrate. A manufacturing method of an epitaxial structure of an LED is also disclosed. The light capturing microstructure includes at least a concave and an insulating material filled in the at least a concave.

### BACKGROUND

1. Technical Field

The invention relates to an epitaxial structure of an LED (light emitting diode) and a manufacturing method thereof, and, in particular, to an epitaxial structure of an LED with a light capturing structure and a manufacturing method thereof.

2. Description of Related Art

LED products are desirable due to their energy saving, high efficiency, fast response time, long lifetime, and the lack of mercury.

In general, an LED epitaxial structure is grown on a sapphire substrate. However, the lattice constant and the thermal expansion coefficient of the epitaxial structure and the sapphire substrate are different, therefore producing thread dislocation. Thread dislocation will limit the LED luminescence. In addition, the light generated by the LED has been limited due to high refractive index, total internal reflection, and light absorption of the epitaxial layer.

As described above, it is important to provide an epitaxial structure of an LED and a manufacturing method of an LED which can solve the above-mentioned problems.

### BRIEF DESCRIPTION OF THE DRAWINGS

The invention will become more fully understood from the detailed description given herein below illustrations only, and thus is not limitative of the present invention, and wherein:

FIG. 1 is a cross-section of an epitaxial structure of an LED according to a first embodiment of the invention.

FIG. 2 is a cross-section of an epitaxial structure of an LED according to a second embodiment of the invention.

FIG. 3 is a flowchart of a manufacturing method of an epitaxial structure of an LED according to an embodiment of the invention.

FIGS. 4-7 are cross-sections each of which corresponds to a step for manufacturing the epitaxial structure of FIG. 1.

### DETAILED DESCRIPTION

An epitaxial structure of an LED and a manufacturing method of the LED, according to preferred embodiments of the invention will be described herein below with reference to the accompanying drawings, wherein the same reference numbers refer to the same elements.

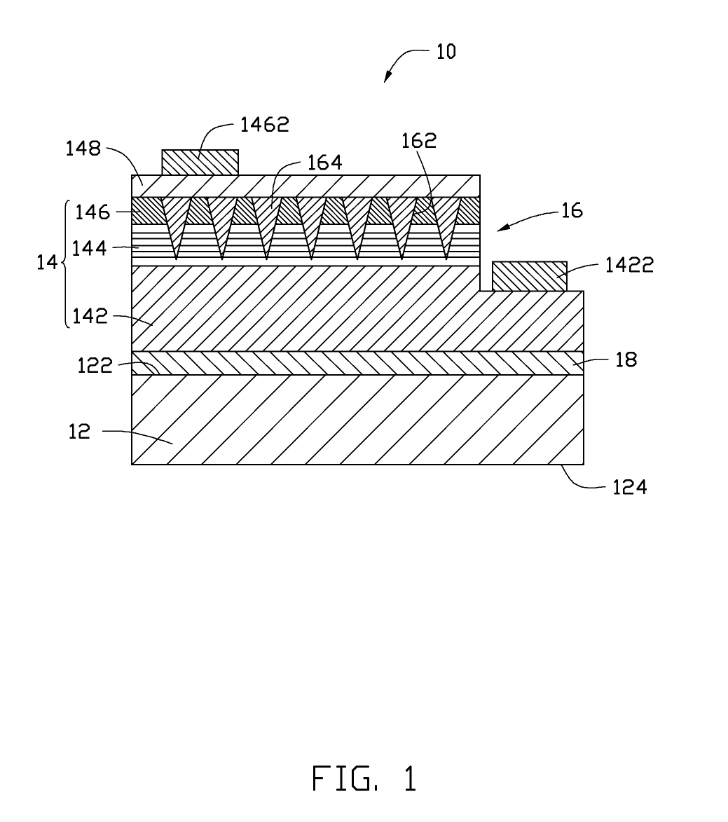

Referring to FIG. 1, which is a cross-section of an epitaxial structure of an LED according to a first embodiment. The epitaxial structure 10 of the LED is a horizontal structure and includes a substrate 12, an epitaxial layer 14, and a light capturing microstructure 16.

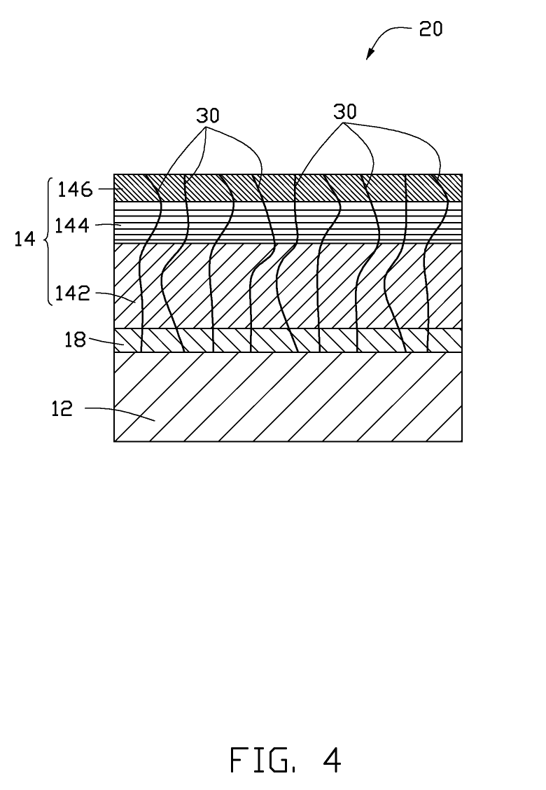

The substrate 12 has a top surface 122 and a bottom surface 124 opposite to the top surface 122. In the embodiment, the substrate 12 is a sapphire substrate. A buffer layer 18 is disposed on the top surface 122. The epitaxial layer 14 is grown on the substrate 12, and in the embodiment, the epitaxial layer 14 is grown on the buffer layer 18. In detail, the epitaxial layer 14 has an N-type semiconductor layer 142, an active layer 144, and a P-type semiconductor layer 146 in sequence. In the embodiment, the N-type semiconductor layer 142 is grown on the buffer layer 18. The buffer layer 18 is used for adapting the lattice constant difference between the substrate 12 and the epitaxial layer 14. The lattice constant difference will cause lattice defect 30 (shown as FIG. 4), and reducing the probability of electron and hole combination in the active layer 144, and reducing the luminescence. In other embodiment, the buffer layer 18 is unnecessary so the N-type semiconductor layer is grown on the top surface 122 of the substrate 12.

The light capturing microstructure 16 is positioned on an upper portion of the epitaxial layer 14 which is distant from the substrate 12. The light capturing microstructure 16 has at least one concave 162 and one insulating material 164, wherein the concave 162 is an inverted cone. The concave 162 is positioned on the upper portion of the epitaxial layer 14 and the insulating material 164 is positioned in the concave 162. The insulating material 164 may be SiO₂, SiN, or SiOxNy. By the help of the concave 162, the light capturing microstructure 16 is used to reduce total internal reflection in the epitaxial structure 10 so as to increase the luminescence.

It is to be noted, in different embodiments, the upper portion may cover the N-type semiconductor layer and a part of the active layer or cover the P-type semiconductor layer and a part of the active layer. In the embodiment, a plurality of concavities 162 are positioned at the P-type semiconductor layer 146 and a part of the active layer 144.

A transparent conductive layer 148 is disposed on the surface of the epitaxial layer 14 to disperse the current flow. In the embodiment, the transparent conductive layer 148 is disposed on the P-type semiconductor layer 146 and the insulating material 164. The material of the transparent conductive layer 148 may be ITO (indium tin oxide) or Ni/Au. A P-type electrode 1462 is electrically connected to the transparent conductive layer 148. An N-type electrode 1422 is electrically connected to the N-type semiconductor layer 142. The P-type electrode 1462 and the N-type electrode 1422 are used to power the LED.

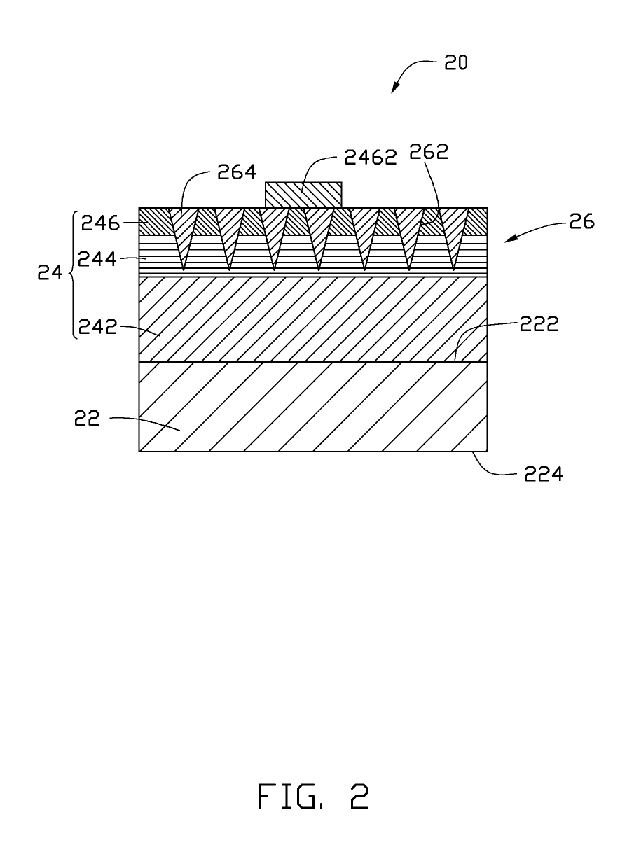

Referring to FIG. 2, which is a cross-section of an epitaxial structure of an LED according to a second embodiment. The epitaxial structure 20 of the LED is a vertical structure and includes a substrate 22, an epitaxial layer 24, and a light capturing microstructure 26.

The substrate 22 has a top surface 222 and a bottom surface 224 opposite to the top surface 222. In the embodiment, the substrate 22 is a metal substrate. The epitaxial layer 24 may be combined with the substrate 22 by laser, chemical technique, mechanical technique, or plating. In details, the epitaxial layer 14 has a P-type semiconductor layer 242, an active layer 244, and an N-type semiconductor layer 246 in sequence. The epitaxial layer 24 is directly formed on the top surface 222 of the substrate 22 with the P-type semiconductor layer 242 contacting with the substrate 22.

The light capturing microstructure 26 is positioned on an upper portion of the epitaxial layer 24 which is distant from the substrate 22. The light capturing microstructure 26 has at least one concave 262 and one insulating material 264, wherein the concave 262 is an inverted cone. The concave 262 is positioned on the upper portion of the epitaxial layer 24 and the insulating material 264 is positioned in the concave 262. The insulating material 264 may be SiO₂, SiN, or SiOxNy. By the help of the concave 262, the light capturing microstructure 26 is used to reduce the total internal reflection in the epitaxial structure 20 so as to increase the luminescence. In the embodiment, a plurality of concavities 262 are positioned at the N-type semiconductor layer 246 and a part of the active layer 244.

An N-type electrode 2462 is electrically connected to the N-type semiconductor layer 246. The N-type electrode 2462 and the metal substrate 224 are used to power the LED.

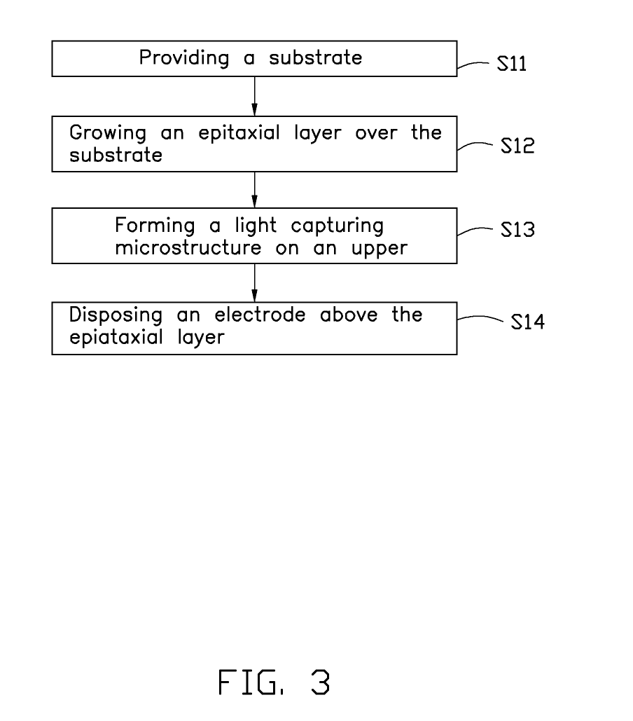

Referring to FIG. 3, which is a flow chart of a manufacturing method of an LED. The manufacturing method includes steps S11 to S15.

Referring to FIG. 4, the step S11 is to provide a substrate 12. In the embodiment, the substrate 12 is a sapphire substrate and a buffer layer 18 is formed on a top surface of the substrate 12.

The step S12 is to grow an epitaxial layer over the substrate 12. In the embodiment, the step S12 further includes the steps of growing an N-type semiconductor layer 142 on the buffer layer 18, growing an active layer 144 on the N-type semiconductor layer 142, and growing a P-type semiconductor layer 146 on the active layer 144.

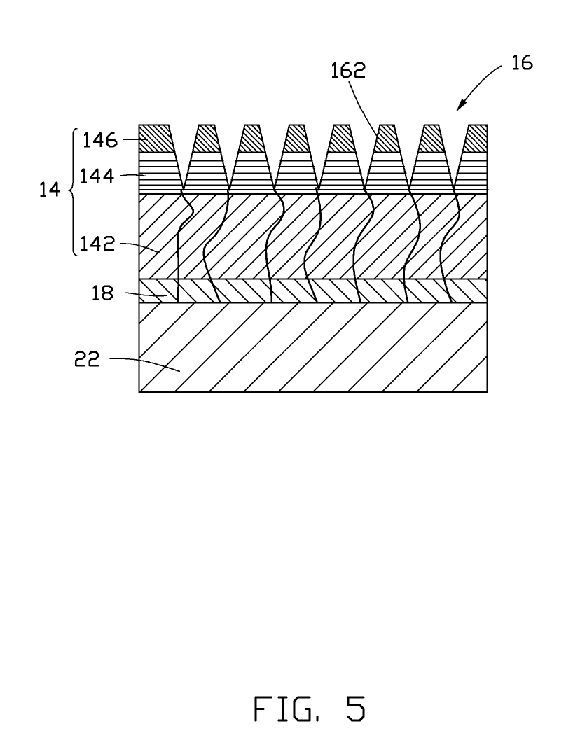

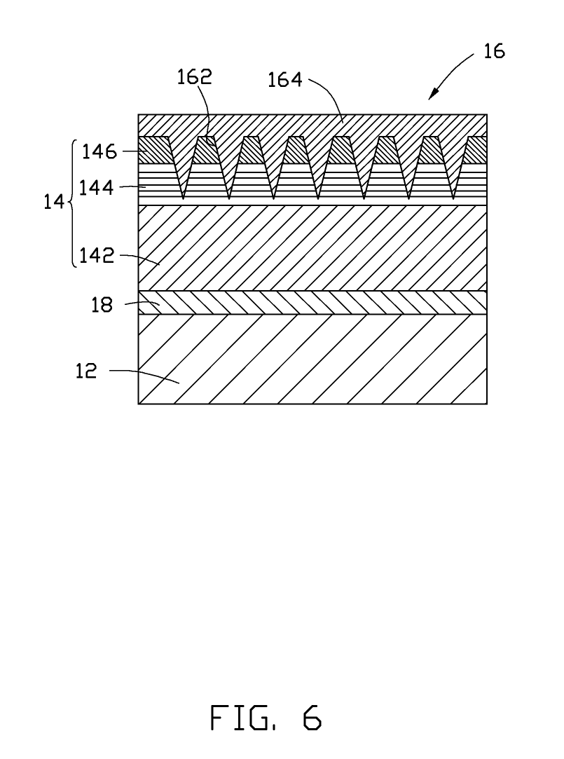

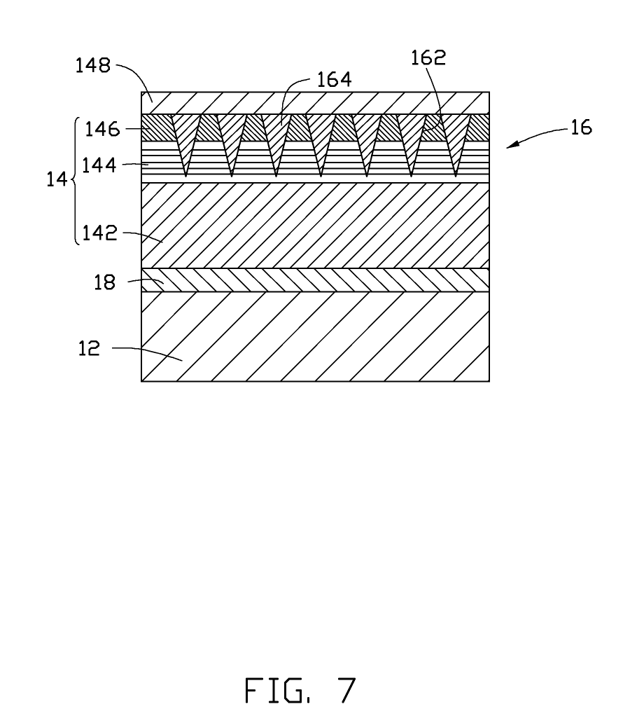

Also referring to FIG. 5, the step S13 is to form a light capturing microstructure 16 on an upper portion of the epitaxial layer 14. In the embodiment, the step S13 further includes the steps of forming a plurality of concavities 162 through the P-type semiconductor layer 146 and a part of active layer 144 by wet etching, forming an insulating material 164 on the P-type semiconductor layer 146 and in the concavities 162 (FIG. 6), and removing a part of insulting material 164 by CMP (Chemical mechanical planarization) or chemical etching so as to level upper surface (shown as FIG. 7). The upper surface is consisted of the P-type semiconductor layer 146 and the insulating material 164.

Also referring to FIG. 7, the step S14 is to dispose an electrode above the epitaxial layer 14. In the embodiment, the step S14 further includes the steps of forming a transparent conductive layer 148 on the upper surface of the epitaxial layer 14, removing a portion of the transparent conductive layer 148, the N-type semiconductor layer 142, the active layer 144, and the P-type semiconductor layer 146 to expose a part of the N-type semiconductor layer 142 (shown as FIG. 1), disposing a P-type electrode 1462 on the transparent conductive layer 148 (shown as FIG. 1), and disposing an N-type electrode 1422 on the exposed N-type semiconductor layer 142 (shown as FIG. 1) to complete the epitaxial structure 10 of the LED.

In summary, the epitaxial structure of LED and manufacturing method thereof using the wet etching to form the light capturing microstructure 16 to reduce the cost and increase the luminescence. The defect in the epitaxial layer is disappeared due to the concavities made by wet etching and the insulating layer filled in the concavities. In addition, the light capturing microstructure can change the lighting angle in order to increase the luminescence.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. An epitaxial structure of a light emitting diode, comprising:
a substrate having a surface;
an epitaxial layer grown on the surface of the substrate and having an N-type semiconductor layer, an active layer, and a P-type semiconductor layer; and
a light capturing microstructure is positioned on an upper portion of the epitaxial layer which is distant from the substrate.

2. The epitaxial structure of claim 1, wherein the light capturing microstructure comprises:
at least a concave positioned on the upper portion of the epitaxial layer; and
an insulating material positioned in the concave.

3. The epitaxial structure of claim 2, wherein the concave is positioned at the P-type semiconductor layer and a part of the active layer.

4. The epitaxial structure of claim 2, wherein the concave is an inverted cone.

5. The epitaxial structure of claim 2, wherein the material of the insulating layer is selected from SiO2, SiN, or SiOxNy.

6. The epitaxial structure of claim 2, wherein an N-type electrode is disposed on the N-type semiconductor layer of the epitaxial layer.

7. The epitaxial structure of claim 1, wherein a transparent conductive layer is disposed on the epitaxial layer.

8. The epitaxial structure of claim 7, wherein a P-type electrode is disposed on the transparent conductive layer.

9. The epitaxial structure of claim 1, wherein the concave is positioned at the N-type semiconductor layer and a part of the active layer.

10. The epitaxial structure of claim 1, wherein a buffer layer is disposed between the substrate and the epitaxial layer.

11. The epitaxial structure of claim 10, wherein the substrate is a sapphire substrate.

12. The epitaxial structure of claim 1, wherein the substrate is a metal substrate.

13. A manufacturing method of a light emitting diode, comprising the steps of:
providing a substrate;
growing an epitaxial layer on the substrate;
forming a light capturing microstructure on an upper portion of the epitaxial layer; and
disposing an electrode above the epitaxial layer.

14. The manufacturing method of claim 13, wherein the step of forming the light capturing microstructure comprises:
forming at least a concave on the upper portion of the epitaxial layer; and
forming an insulating material in the concave.

15. The manufacturing method of claim 13, further comprising disposing a buffer layer on a surface of the substrate after providing the substrate, and the epitaxial layer is grown on the buffer layer.

16. The manufacturing method of claim 13, wherein the step of forming the light capturing microstructure includes wet etching.
